(19) United States
(12) Patent Application Publication
(10) Pub. No.: US 2023/0091157 A1
(43) Pub. Date: Mar. 23, 2023

(54) Laminated thin heat dissipation device and method of manufacturing the same

(71) Applicant: Ke Chin LEE, Taoyuan City (TW)

(72) Inventor: Ke Chin LEE, Taoyuan City (TW)

(21) Appl. No.: 17/996,110

(22) PCT Filed: Apr. 17, 2020
(86) PCT No.: PCT/CN2020/085323

§ 371 Date: Oct. 13, 2022

(51) Int. Cl. F28D 15/04; H05K 7/20; F28D 15/02

(52) U.S. Cl. CPC F28D 15/046; H05K 7/20336; F28D 15/0233

(57) ABSTRACT

The present invention is related to a laminated thin heat dissipation device mainly comprising an upper plate, at least one first layer plate, at least one second layer plate, a lower plate and a working fluid, the first, second layer plates having at least one first, second hollow slots respectively, wherein the upper plate, the first layer plate, the second layer plate and the lower plate are laminated to form a hollow body, the first hollow slot and the second hollow slot are communicated with each other and form an enclosed chamber, the enclosed chamber includes at least one first fluid channel and at least one second fluid channel, the enclosed chamber of the hollow body is filled with the working fluid, the first fluid channel serves as a vapor flow path, and the second fluid channel serves as a condensed fluid flow path.

### BACKGROUND OF THE INVENITON

### Field of the Invention

The present invention relates to a laminated thin heat dissipation device and a method of manufacturing the same, in particular to a thin heat dissipation device suitable for a portable electronic device and a method of manufacturing the same.

### Description of the Related Art

With the continuous improvement of the computing power of portable electronic devices, the demand for heat dissipation has become increasingly important. In addition, the current trend is constantly towards a light, thin, compact portable electronic device, and this undoubtedly limits the arrangement space of the heat dissipation device.

Heat dissipation devices for portable electronic devices, for example, U.S. Pat. No. 9,565,786, entitled “SHEET-LIKE HEAT PIPE, AND ELECTRONIC DEVICE PROVIDED WITH THE SAME”, have been developed in the prior art. However, as described in the patent literature, the inside of the traditional heat pipe still has to be provided with a capillary structure for returning the condensed working fluid, and the common capillary structure includes a mesh, a fibrous body, a powder sintered body or micro-grooves.

Furthermore, the capillary structure in the heat pipe not only increases the manufacturing cost, but also the manufacturing process is very complicated. For example, in order to fix the capillary structure such as a mesh, a fibrous body, or a powder sintered body, it must be adhered by heating or be sintered so that an annealing process is necessarily required. However, annealing may change material properties and affect reliability. On the other hand, if the micro-grooves are adopted, etching, sputtering or other processes for forming a micro-structure, such as CVD or PVD, must be performed. In addition, the capillary structure in the heat pipe must also have a considerable volume for gas-liquid circulation of sufficient working fluid. As a result, the overall thickness of the heat pipe is limited and cannot be further reduced, and the thickness of the electronic device is indirectly affected.

Moreover, in another related prior art, it is also found that a semiconductor manufacturing process is used to prepare a thin heat dissipation device, for example, U.S. Patent Publication No. 2020/025458, entitled “VAPOR CHAMBER, ELECTRONIC DEVICE, METALLIC SHEET FOR VAPOR CHAMBER AND MANUFACTURING METHOD OF VAPOR CHAMBER”, in which photolithography and etching for semiconductor manufacturing are used to prepare a working fluid flow path. However, these processes are expensive, time-consuming, difficult for mass production, and also limits the form of the working fluid flow path.

On the other hand, in the PCT application entitled “THIN HEAT DISSIPATION DEVICE AND METHOD FOR MANUFACTURING THE SAME” (the application No. PCT/US2020/013981), previously filed by the applicant of the present application, a variety of innovative structures and manufacturing methods of heat dissipation devices are provided, most of them are formed by die stamping, the structures are quite simple, and compared with the related prior art, the manufacturing cost and the process time consumed have been significantly improved. However, the present applicant has been more active in developing a thin heat dissipation device which is more reliable, has a longer service life and can flexibly change various flow channel structures according to various needs, and its manufacturing method.

### SUMMARY OF THE INVENTION

A main object of the present invention is to provide a laminated thin heat dissipation device, which has a simple structure, high reliability, a long service life and an easily and flexibly changed structural dimension and a thin thickness.

Another object of the present invention is to provide a method of manufacturing a laminated thin heat dissipation device, which is simple, has high yield rate, and a low manufacturing cost, and is suitable for mass production.

In order to achieve the above objects, a laminated thin heat dissipation device of the present invention mainly comprises an upper plate, at least one first layer plate, at least one second layer plate, a lower plate and a working fluid; the at least one first layer plate each has at least one first hollow slot penetrating therethrough, the at least one second layer plate each has at least one second hollow slot penetrating therethrough, wherein the upper plate, the at least one first layer plate, the at least one second layer plate and the lower plate are laminated to form a hollow body, the at least one first hollow slot and the at least one second hollow slot are communicated with each other and form an enclosed chamber; the enclosed chamber includes at least one first fluid channel and at least one second fluid channel; and the enclosed chamber of the hollow body is filled with the working fluid.

As can be known from the above, in the present invention, the first fluid channel and the second fluid channel communicated with each other are formed by stacking the upper plate, the first hollow slot of the first layer plate, the second hollow slot of the second layer plate and the lower plate, wherein one fluid channel serves as a vapor flow path, and the other fluid channel serves as a condensed fluid flow path.

Accordingly, the overall structure of the device of the present invention is simple and reliable, the cost is relatively low, and the heat dissipation efficiency is excellent; and the size or shape of the device can be easily and flexibly changed, for example, the area, thickness and shape of the device can be changed according to the required heat dissipation efficiency and the actual matching object to be heat dissipated.

Preferably, a height of a boundary surface between the first fluid channel and the second fluid channel in the laminated thin heat dissipation device of the present invention may be less than or equal to 0.1 mm. Since the channel less than or equal to 0.1 mm in height can provide excellent capillary action, it can replace the conventional capillary structure such as a mesh, a fibrous body or a powder sintered body. Furthermore, the first fluid channel and the second fluid channel may extend in the longitudinal direction of the hollow body; and the first fluid channel and the second fluid channel may be arranged side by side in the widthwise direction of the hollow body or stacked in the height direction and communicated with each other.

Furthermore, in the laminated thin heat dissipation device of the present invention, the first hollow slot of the first layer plate may include a plurality of first flow guiding portions and a first converging portion, the plurality of first flow guiding portions may extend in the longitudinal direction of the hollow body, and the first converging portion may extend in the widthwise direction of the hollow body and be communicated with the plurality of first flow guiding portions; on the other hand, the second hollow slot of the second layer plate may include a plurality of second flow guiding portions and a second converging portion, the plurality of second flow guiding portions may extend in the longitudinal direction of the hollow body, and the second converging portion may extend in the widthwise direction of the hollow body and be communicated with the plurality of second flow guiding portions. In other words, in the present invention, by means of the arrangement of the above-mentioned flow guiding portions and converging portion, a heat dissipation plate with multiple heat conduction channels can be formed, which can provide heat transfer and heat dissipation in a large area, and the thickness of which can be kept relatively thin. Moreover, the first converging portion and the second converging portion can provide the confluence of the working fluid in form of gas and the working fluid in form of liquid, so as to achieve the effect of temperature uniformity across the entire heat dissipation device.

In order to achieve the above object, the present invention provides a method of manufacturing a laminated thin heat dissipation device, which comprises the steps of: (A) providing an upper plate, at least one first layer plate, at least one second layer plate and a lower plate, each first layer plate having at least one first hollow slot penetrating therethrough, each second layer plate having at least one second hollow slot penetrating therethrough; (B) laminating the upper plate, the at least one first layer plate, the at least one second layer plate and the lower plate to form a hollow body; and (C) filling a working fluid into the hollow body and degassing the hollow body, and then sealing the hollow body so as to form an enclosed chamber, wherein the enclosed chamber includes at least one first fluid channel and at least one second fluid channel.

Accordingly, the manufacturing method provided by the present invention is simple and low-cost. The first hollow slot and the second hollow slot can be formed simply by machining, i.e. die cutting, and then, the upper and lower plates and the first and second layer plates are directly laminated without etching or sintering and additional processes necessary for formation of the conventional capillary structure. It is a very innovative and ingenious manufacturing method.

### BRIEF DESCRIPTION OF THE DRAWINGS

FIG. 1A is a perspective view of a first embodiment of the present invention.

FIG. 1B is a cross-sectional view of the first embodiment of the present invention.

FIG. 1C is an exploded view of the first embodiment of the present invention.

FIG. 2A is a cross-sectional view of a second embodiment of the present invention.

FIG. 2B is an exploded view of the second embodiment of the present invention.

FIG. 3 is a cross-sectional view of a third embodiment of the present invention.

FIG. 4A is a cross-sectional view of a fourth embodiment of the present invention.

FIG. 4B is an exploded view of the fourth embodiment of the present invention.

FIG. 5A is a cross-sectional view of a fifth embodiment of the present invention.

FIG. 5B is a front view of a first layer plate of the fifth embodiment of the present invention.

FIG. 5C is a front view of a second layer plate of the fifth embodiment of the present invention.

### DESCRIPTION OF THE PREFERRED EMBODIMENTS

Before a laminated thin heat dissipation device and a method of manufacturing the same according to the present invention are described in detail in the embodiments, it should be noted that in the following description, similar components will be designated by the same reference numerals. Furthermore, the drawings of the present invention are for illustrative purposes only, they are not necessarily drawn to scale, and not all details are necessarily shown in the drawings.

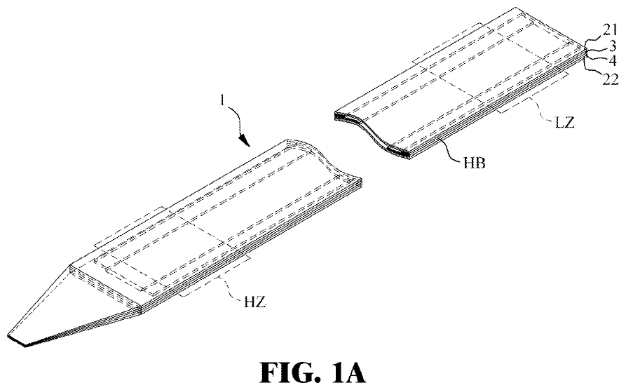

Please refer to FIGS. 1A, 1B and 1C together. FIG. 1A is a perspective view of a first embodiment of a laminated thin heat dissipation device 1 according to the present invention, FIG. 1B is a cross-sectional view of the first embodiment of the laminated thin heat dissipation device 1 according to the present invention, and FIG. 1C is an exploded view of the first embodiment of the laminated thin heat dissipation device 1 according to the present invention.

As shown in FIG. 1, the laminated thin heat dissipation device 1 of this embodiment is in form of an elongated shape, but the heat dissipation device of the present invention is not limited to this type, and can be in any shape, such as a flat-plate shape. In addition, as shown in FIG. 1, the two ends of the device are an evaporation zone HZ and a condensation zone LZ respectively, wherein the evaporation zone HZ is used to be in contact with a high-temperature device. A working fluid is evaporated at high temperature in the evaporation zone HZ, flows back to the condensation zone LZ in form of gas and condenses into liquid, and then flows to the evaporation zone HZ in form of liquid through a capillary structure for transferring and dissipating heat dissipation by continuous circulation.

However, the laminated thin heat dissipation device 1 of this embodiment mainly includes an upper plate 21, a first layer plate 3, a second layer plate 4 and a lower plate 22, wherein the upper plate 21, the first layer plate 3, the second layer plate 4 and the lower plate 22 are strip-shaped plates with the same outer contour, the first layer plate 3 is provided with a first hollow slot 31 penetrating therethrough; the second layer plate 4 is also provided with a second hollow slot 41 penetrating therethrough.

Furthermore, the upper plate 21, the first layer plate 3, the second layer plate 4 and the lower plate 22 are laminated to form a hollow body HB, and the first hollow slot 31 and the second hollow slot 41 are communicated with each other and form an enclosed chamber C; and the enclosed chamber C includes a first fluid channel CH1 and two second fluid channels CH2; the enclosed chamber C of the hollow body HB is filled with the working fluid, which may be ammonia, acetone, methanol, ethanol, heptane or water. The working fluid can be appropriately selected according to different working temperature ranges.

The first fluid channel CH1 and the second fluid channels CH2 extend in the longitudinal direction of the hollow body HB; and the first fluid channel CH1 and the second fluid channels CH2 are arranged side by side in the widthwise direction of the hollow body HB and are communicated with each other. In this embodiment, the first fluid channel CH1 serves as a channel for the vapor, and the second fluid channels CH2 serve as a structure with capillary effect, i.e. channels for returning the condensed fluid.

Specifically, as shown in FIG. 1B and FIG. 1C, in this embodiment, the cross-sectional area of the first hollow slot 31 is larger than the cross-sectional area of the second hollow slot 41. Therefore, as can be seen from the cross-sectional view of FIG. 1B, when the first layer plate 3 and the second layer plate 4 are stacked on each other, the cross section of the enclosed chamber C is T-shaped. The first fluid channel CH1 is formed by an overlap portion between the first hollow slot 31 and the second hollow slot 41; and the second fluid channels CH2 are a portion of the first hollow slot 31 which does not overlap with the second hollow slot 41 and are located at the lateral sides of the upper of the first fluid channel CH1.

Furthermore, the thickness T of the first layer plate 3 in this embodiment is 40 μm so a height of a boundary surface between the first fluid channel CH1 and the second fluid channel CH2 is also 40 μm. In fact, according to the actual research result, the capillary effect can be generated when the height of the channel is less than or equal to 0.1 mm, and the smaller the height, the more obvious the capillary phenomenon. Accordingly, since the height of the second fluid channel CH2 in this embodiment is only 40 μm, it can provide an excellent effect of liquid return.

Furthermore, the thickness of other plates including the second layer plate 4, the upper plate 21 and the lower plate 22 in this embodiment is also 40 μm so the overall thickness of the device is only 160 μm. In addition, all the plates in this embodiment can be made of a material with excellent thermal conductivity, such as copper. Since the overall thickness of the device is quite thin, the strength (hardness) must also be considered at the same time. Therefore, copper alloy, aluminum, aluminum alloy, iron, stainless steel, composite material of copper and stainless steel (Cu-SUS), or composite material of nickel and stainless steel (Ni-SUS) can also be selected.

Accordingly, when the working fluid absorbs heat in the evaporation zone HZ and is evaporated into vapor, a local high pressure is generated in the chamber so that the evaporated working fluid is urged to the condensation zone LZ at a high speed through the first fluid channel CH1 and condensed into liquid in the condensation zone LZ and then flows back to the evaporation zone HZ through the capillary structure of the second fluid channels CH2 for continuous circulation. In other words, by way of the liquid-gas two-phase change of the working fluid continuously circulating in the chamber, that is, the evaporated working fluid and the condensed working fluid flow back and forth between the heat-absorbing end (the evaporation zone HZ) and the heat-dissipating end (the condensation zone LZ), the surface of the chamber exhibits the characteristic of rapid temperature uniformity for the purpose of heat transfer and heat removal.

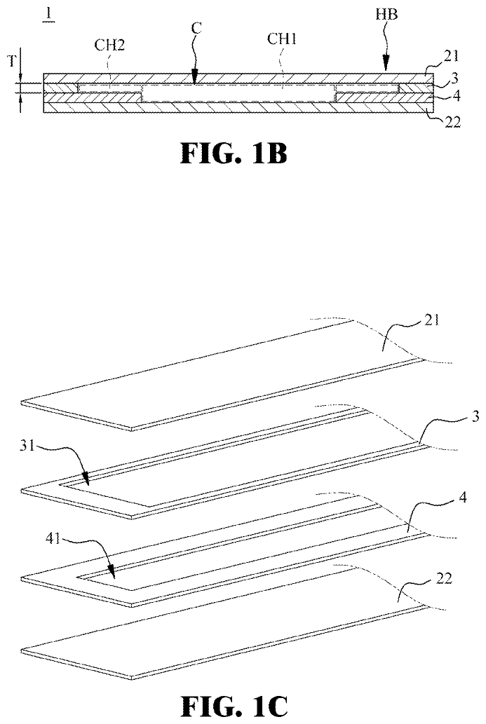

Please refer to FIG. 2A and FIG. 2B at the same time. FIG. 2A is a cross-sectional view of a second embodiment of the present invention, and FIG. 2B is an exploded view of the second embodiment of the present invention. The main difference between this embodiment and the aforementioned first embodiment lies in that the cross-sectional areas of the first hollow slot 31 and the second hollow slot 41 are the same, but they are not arranged at the center of the first layer plate 3 and the second layer plate 4 and are offset from each other toward two lateral sides in the widthwise direction.

Specifically, the first hollow slot 31 and the second hollow slot 41 are offset from each other in the widthwise direction of the device and include an overlap portion and a non-overlap portion, wherein the overlap portion forms a first fluid channel CH1; the non-overlap portion forms two second fluid channels CH2, which are located on the left sidewall and right sidewall of the upper portion and the lower portion of the first fluid channel CH1 respectively. In other words, in the cross-section shown in FIG. 2A, the first fluid channel CH1 and the second fluid channels CH2 are substantially Z-shaped. However, the advantage of this embodiment lies in that the specifications of the first layer plate 3 and the second layer plate 4 are completely the same, that is, only one kind of layer plate needs to be manufactured, and they are offset with each other during assembly. It is very advantageous in manufacturing cost.

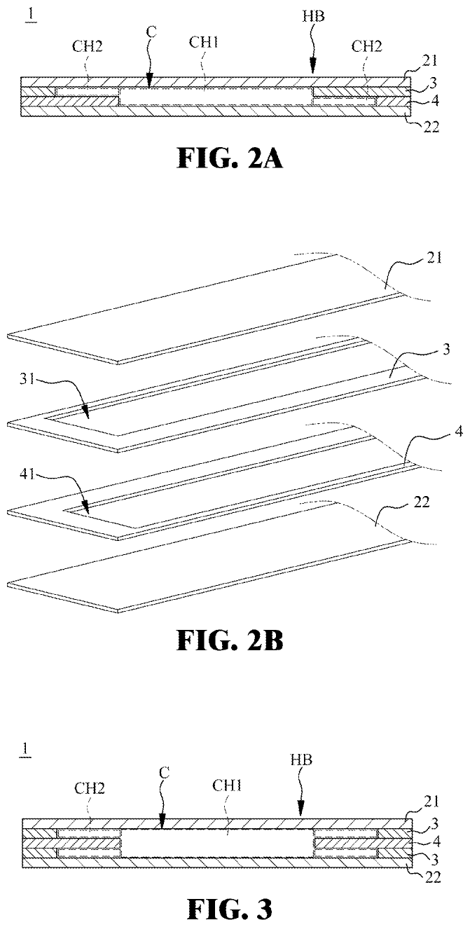

Please refer to FIG. 3. FIG. 3 is a cross-sectional view of a third embodiment of the laminated thin heat dissipation device according the present invention. The main difference between this embodiment and the aforementioned first embodiment lies in that in this embodiment, one more first layer plate 3 is added between the second layer plate 4 and the lower plate 22. However, by means of this configuration, the number of the second fluid channels CH2 can be doubled, thereby greatly increasing the amount of condensed working fluid flowing back and significantly improving the efficiency. Accordingly, one of the advantages of the present invention can be clearly shown by this embodiment, that is, the volume of the first fluid channel CH1 and the number of the second fluid channels CH2 can be easily adjusted by increasing or decreasing the number of the first and second layer plates, so as to meet heat removal requirements for various specifications.

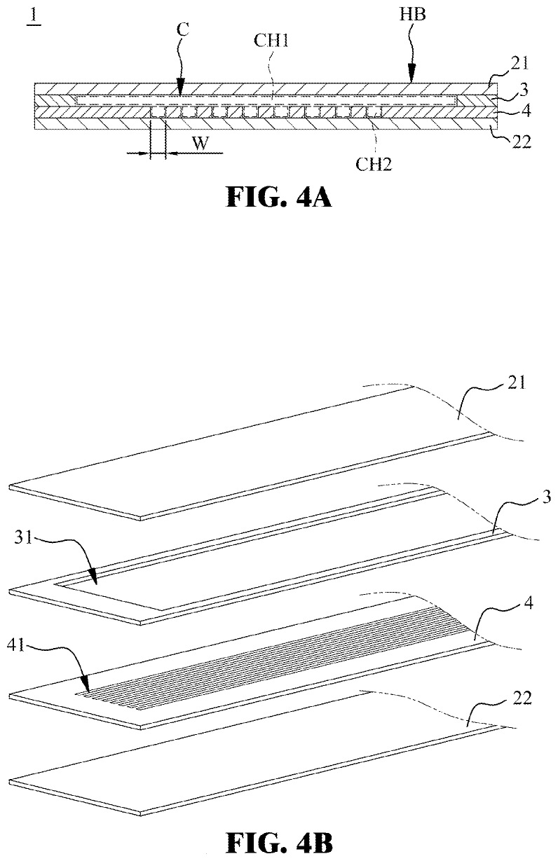

Please refer to FIG. 4A and FIG. 4B at the same time. FIG. 4A is a cross-sectional view of a fourth embodiment of the present invention, and FIG. 4B is an exploded view of the fourth embodiment of the present invention. As shown in the figures, the main difference between this embodiment and the previous embodiments lies in that, in the first to third embodiments, the first fluid channel CH1 and the second fluid channels CH2 are arranged side by side in the widthwise direction of the hollow body HB and communicated with each other while the first fluid channel CH1 and the second fluid channels CH2 in this embodiment are stacked in the height (thickness) direction of the hollow body HB.

Specifically, the second layer plate 4 of this embodiment is provided with a plurality of second hollow slots 41, which are equidistantly distributed in the widthwise direction. The width W of each second fluid channel CH2 is 0.1 mm. In other words, as mentioned above, a width of a boundary surface between the first fluid channel CH1 and the second fluid channel CH2 is less than or equal to 0.1 mm, thereby forming a capillary structure. Therefore, the second fluid channel CH2 in this embodiment can serve as a channel for returning the condensed working fluid.

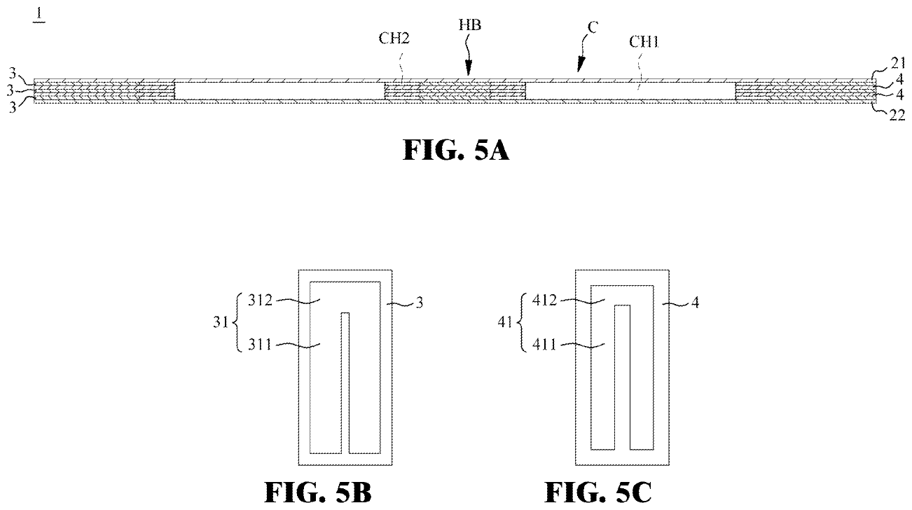

Please refer to FIGS. 5A, 5B, and 5C together. FIG. 5A is a cross-sectional view of a fifth embodiment of the present invention, FIG. 5B is a front view of a first layer plate of the fifth embodiment of the present invention, and FIG. 5C is a front view of a second layer plate of the fifth embodiment of the present invention. This embodiment is intended to show that the present invention is not limited to an elongated heat pipe and can be formed into a vapor chamber.

Specifically, the heat dissipation device of this embodiment comprises three first layer plate 3, two second layer plates 4, an upper plate 21 and a lower plate 22 so that a vapor chamber with a 7-layer structure is formed. Furthermore, the first hollow slot 31 of the first layer plate 3 of this embodiment includes two first flow guiding portions 311 and a first converging portion 312, wherein the two first flow guiding portions 311 extend in the longitudinal direction of the first layer plate, and the first flow converging portion 312 extends in the widthwise direction of the first layer plate 3 and is communicated with the first flow guiding portions 311. Similarly, the second hollow slot 41 of the second layer plate 4 of this embodiment includes two second flow guiding portions 411 and a second converging portion 412, wherein the two second flow guiding portions 411 extend in the longitudinal direction of the second layer plate 4, and the second converging portion 412 extends in the widthwise direction of the second layer plate 4 and is communicated with the second flow guiding portions 411.

Taking the heat dissipation requirement of a smart phone as an example, each element of this embodiment can be sized as follows: the upper plate 21, the lower plate 22 and each layer plate can be of a length of 50 mm and a width of 24 mm; the first flow guiding portion 311 can be of a length of 36 mm and a width of 8 mm; the first converging portion 312 can be of a length of 18 mm and a width of 8 mm; the second flow guiding portion 411 can be of a length of 37 mm and a width of 6 mm; the second converging portion 412 can be of a length of 16 mm and a width of 5 mm. In addition, the thicknesses of all stacked plates in this embodiment are 40 μm so the overall thickness of the device is only 0.28 mm.

Accordingly, as shown in this embodiment, the present invention is not limited to an elongated thin heat pipe, but also includes a flat plate-shaped vapor chamber. Moreover, the present invention can flexibly adjust various parameters such as the size, number and shape of the first fluid channel CH1, the second fluid channel CH2 and each plate depending on actual requirements, such as the size and shape of an electronic device or the position, size or shape of an object to be heat-dissipated.

The first embodiment is taken as an example below to illustrate a manufacturing method of the present invention. First, in the step (A), an upper plate 21, a first layer plate 3, a second layer plate 4 and a lower plate 22 are provided, wherein the first layer plate 3 and the second layer plate 4 have been respectively formed with the first hollow slot 31 and the second hollow slot 41 in advance. In this embodiment, the first hollow slot 31 and the second hollow slot 41 are formed by die cutting, only using an ordinary machining equipment (a stamping press). It is very suitable for mass production and has a quite low cost.

However, the present invention is not limited to the fact that the first hollow slot 31 and the second hollow slot 41 are formed by die cutting, and other equivalent machining methods such as chemical etching, electrical discharge machining, 3D printing, PVD, CVD or milling are also applicable. It should be particularly noted that if it is necessary to form a relatively fine hollow slot, such as the second hollow slot 41 in the fourth embodiment, using etching process, physical, chemical vapor deposition process or the like which is ordinary in semiconductor manufacturing can be considered since the relatively fine hollow slot exceeds the limit of general machining.

Next, in the step (B), the upper plate 21, the first layer plate 3, the second layer plate 4 and the lower plate 22 are laminated to form a hollow body HB. In other words, taking the first embodiment of the present invention as an example, the lower plate 22, the second layer plate 4, the first layer plate 3, and the upper plate 21 are stacked in sequence from bottom to top, and then, all the plates can be bonded together by diffusion bonding. Of course, in this bonding step, a through hole must be reserved for injecting a working fluid into the hollow body and degassing the hollow body.

Furthermore, in the step (C), the working fluid is injected into the hollow body HB, the hollow body HB is degassed, and then the hollow body HB is sealed to form an enclosed chamber C. That is, for example, after degassing the hollow body by means of heating or vacuum or a combination thereof and sealing the through hole by means of riveting, welding or diffusion bonding to form the enclosed chamber C, the device of the present invention is completed. Accordingly, the manufacturing process of the present invention is quite simple, can be completed only by general machining, is very suitable for mass production, and has a quite low cost and extremely high production efficiency. Moreover, the process conditions and product specifications can be easily and flexibly changed according to the actual demand so it is an innovative invention that is highly creative, practical and can be mass-produced industrially.

The above-mentioned embodiments are only examples for the convenience of description, and the scope of the present invention should be permitted by the following claims, rather than limited to the above-mentioned embodiments.

What is claimed is:

1. A laminated thin heat dissipation device, comprising:
an upper plate;
at least one first layer plate, each having at least one first hollow slot penetrating therethrough;
at least one second layer plate, each having at least one second hollow slot penetrating therethrough;
a lower plate; and
a working fluid,
wherein the upper plate, the at least one first layer plate, the at least one second layer plate, and the lower plate are laminated to form a hollow body; the at least one first hollow slot and the at least one second hollow slot are communicated with each other and form an enclosed chamber; the enclosed chamber includes at least one first fluid channel and at least one second fluid channel; the working fluid is filled in the enclosed chamber of the hollow body;
wherein the first fluid channel and the second fluid channel extend in a longitudinal direction of the hollow body; the first fluid channel and the second fluid channel are arranged side by side in a widthwise direction of the hollow body and communicated with each other.

2. The laminated thin heat dissipation device as claimed in claim 1, wherein a width of a boundary surface between the first fluid channel and the second fluid channel is less than or equal to 0.1 mm.

3. (canceled)

4. The laminated thin heat dissipation device as claimed in claim 1, wherein a cross-sectional area of the first hollow slot is greater than a cross-sectional area of the second hollow slot; the first fluid channel is formed by an overlap portion between the at least one first hollow slot and the at least one second hollow slot, the second fluid channel is a portion of the at least one first hollow slot which does not overlap with the at least one second hollow slot.

5. The laminated thin heat dissipation device as claimed in claim 1, wherein the at least one first hollow slot and the at least one second hollow slot are offset from each other to form an overlap portion and a non-overlap portion; the first fluid channel is formed by the overlap portion, and the second fluid channel is formed by the non-overlap portion.

6. (canceled)

7. The laminated thin heat dissipation device as claimed in claim 1, wherein the at least one first hollow slot of the at least one first layer plate comprises a plurality of first flow guiding portions and a first converging portion, the plurality of first flow guiding portions extend in a longitudinal direction of the hollow body, the first converging portion extends in a widthwise direction of the hollow body and is communicated with the plurality of first flow guiding portions; the at least one second hollow slot of the at least one second layer plate comprises a plurality of second flow guiding portions and a second converging portion, the plurality of second flow guiding portions extend in the longitudinal direction of the hollow body, the second converging portion extends in the widthwise direction of the hollow body and is communicated with the plurality of second flow guiding portions.

8. A method of manufacturing a laminated thin heat dissipation device, comprising the steps of:
(A) providing an upper plate, at least one first layer plate, at least one second layer plate, and a lower plate, each first layer plate having at least one first hollow slot penetrating therethrough, each second layer plate having at least one second hollow slot penetrating therethrough;
(B) laminating the upper plate, the at least one first layer plate, the at least one second layer plate and the lower plate to form a hollow body; and
(C) filling a working fluid into the hollow body and degassing the hollow body, and then sealing the hollow body so as to form an enclosed chamber, wherein the enclosed chamber includes at least one first fluid channel and at least one second fluid channel; the first fluid channel and the second fluid channel extene in a longitudinal direction of the hollow body; the first fluid channel and the second fluid channel are arranged side by side in a widthwise direction of the hollow body and communicated with each other.

9. The method of manufacturing a laminated thin heat dissipation device as claimed in claim 8, wherein a thickness of at least one of the first layer plate and the second layer plate is less than or equal to 0.1 mm.

10. The method of manufacturing a laminated thin heat dissipation device as claimed in claim 8, wherein the at least one first hollow slot of the at least one first layer plate and the at least one second hollow slot of the at least one second layer plate are formed by die cutting.
